(19) United States
(12) Patent Application Publication
(10) Pub. No.: US 2013/0163202 A1
(43) Pub. Date: Jun. 27, 2013

(54) ELECTRONIC DEVICE WITH HEAT DISSIPATING MODULE

(71) Applicants: XIAO-FENG MA, Shenzhen City (CN); LEI LIU, Shenzhen City (CN)

(72) Inventors: XIAO-FENG MA, Shenzhen City (CN); LEI LIU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD ., Shenzhen City (CN)

(21) Appl. No.: 13/437,020

(22) Filed: Apr. 2, 2012

(30) Foreign Application Priority Data
Dec. 26, 2011 (CN) 201110440369.0

(51) Int. Cl. H05K 7/20

(52) U.S. Cl. 361/695; 361/720

(57) ABSTRACT

An electronic device includes a housing, a power supply unit (PSU) bracket fixed in the housing. The PSU bracket includes an idle PSU receiving portion. A heat dissipating module is received in the idle PSU receiving portion.

### BACKGROUND

1. Technical Field

The present disclosure relates to electronic devices, and particularly, to an electronic device with a heat dissipating module.

2. Description of Related Art

Electronic devices, such as servers, are powered by power supply units (PSU). For being repaired easily, an electronic device usually includes two or more PSUs received in two or more PSU receiving areas. When one of the PSUs is removed from the electronic device, the other PSUs can power the electronic device. However, while the one PSU receiving area for the removed PSU is empty, the airflow in the enclosure of the electronic device may be unfavorably altered.

### BRIEF DESCRIPTION OF THE DRAWINGS

Many aspects of the present embodiments can be better understood with reference to the following drawings. The components in the drawing are not necessarily drawn to scale, the emphasis instead being placed upon clearly illustrating the principles of the present embodiments. Moreover, in the drawing, like reference numerals designate corresponding parts throughout the several views.

FIG. 1 is an isometric view of an electronic device of an exemplary embodiment, with certain components omitted for clarity.

FIG. 2 is an exploded, isometric view of FIG. 1, wherein the electronic device includes a heat dissipating module.

FIG. 3 is an exploded, isometric view of the heat dissipating module of FIG. 2.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

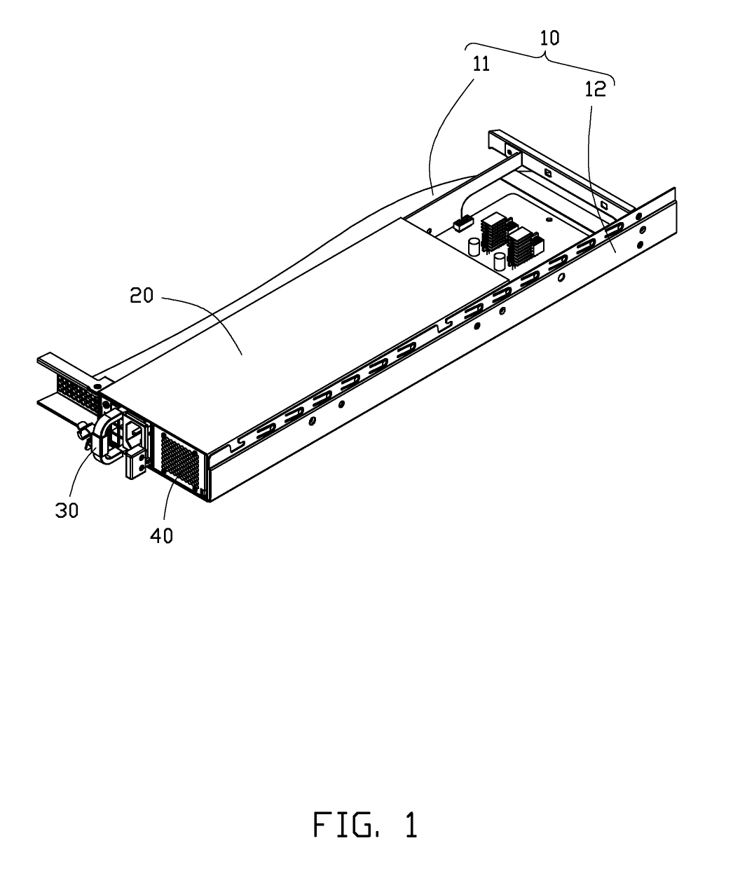

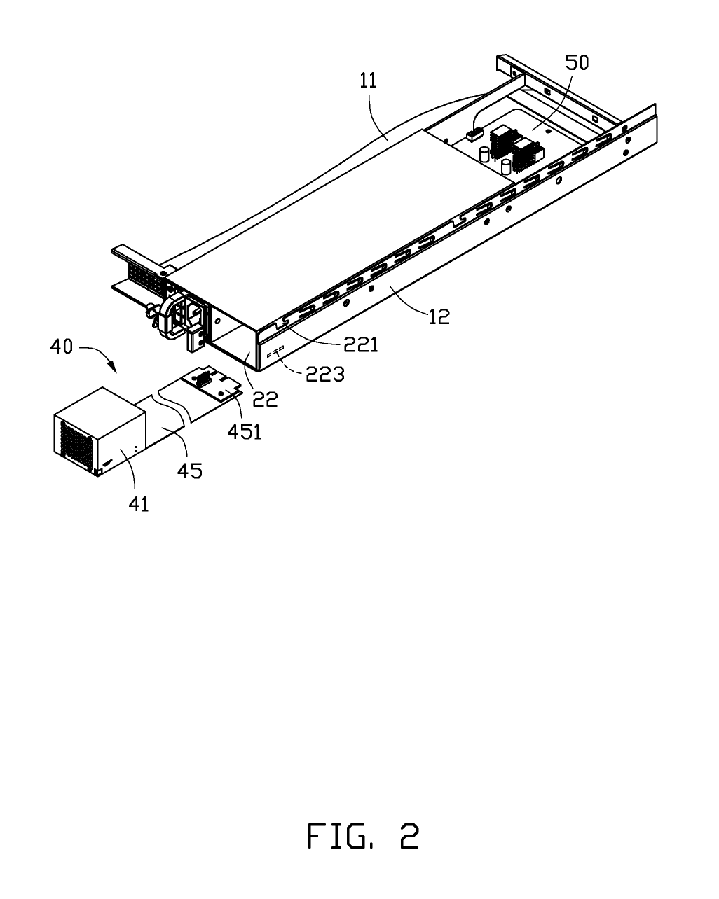

Referring to FIG. 1 and FIG. 2, an embodiment of an electronic device includes a housing 10, a power supply unit (PSU) bracket 20, a PSU 30, a heat dissipating module 40, and a circuit board 50.

The housing 10 includes a bottom wall 11 and a sidewall 12 extending perpendicularly from a side of the bottom wall 11.

The PSU bracket 20 is fixed on the bottom wall 11, adjacent to the sidewall 12. The PSU bracket 20 includes two receiving portions 22 for respectively receiving the PSU 30 and the heat dissipating module 40. Each receiving portion 22 is a substantially rectangular frame defining two openings in opposite ends. The PSU bracket 20 includes a side plate 221 facing the sidewall 12. The side plate 221 defines a locking slot 223 in a front end of the side plate 221.

The circuit board 50 is fixed on the bottom wall 11 and aligns with back openings of the receiving portions 22 of the PSU bracket 20.

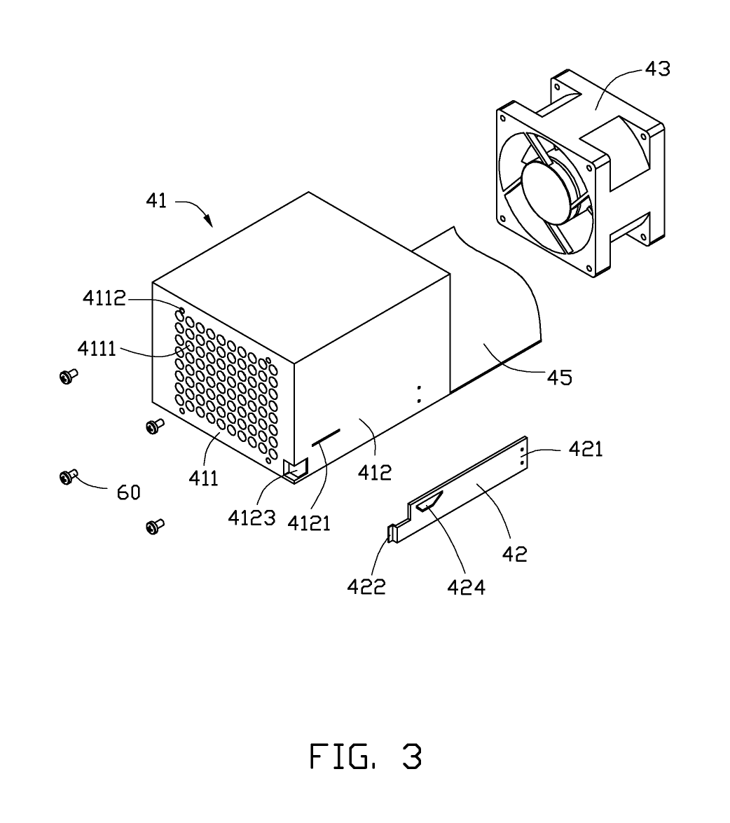

Referring to FIG. 3, the heat dissipating module 40 includes a rectangular-box shaped mounting frame 41, a fan 43 received in the mounting frame 41, and a connecting plate 45 extending from a bottom side of the mounting frame 41 and electrically connected to the fan 43. The mounting frame 41 includes a first plate 411 and a second plate 412 perpendicularly connected to a side of the first plate 411. The first plate 411 defines a plurality of vents 4111. Four mounting holes 4112 are respectively defined in four corners of the first plate 411. The fan 43 is attached to the first plate 411. Four screws 60 extend through the mounting holes 4112 to screw into the fan 43.

The second plate 412 defines a through slot 4121 adjacent to the first plate 411. A through hole 4123 is defined in a joint between the first plate 411 and the second plate 412. A resilient piece 42 is arranged in the mounting frame 41. The resilient piece 42 includes a fixing end 421 fixed on an inner side of the second plate 412, an operation end 422 opposite to the fixing end 421 and extending through the through hole 4123, and a locking portion 424 protruding from the resilient piece 42 and adjacent to the operation end 422. The locking portion 424 extends through the through slot 4121.

A connector 451 is set on an end of the connecting plate 45 away from the mounting frame 41.

In assembly, the heat dissipating module 40 is inserted in one of the receiving portions 22. The locking portion 424 abuts against the side plate 221 to be deformed, until the locking portion 424 is locked to the locking slot 223. The connector 451 is connected to the circuit board 50, to electrically connect the fan 43 to the circuit board 50. The first plate 411 covers the front opening of the receiving portion 22.

If it is needed to release the heat dissipating module 40 from the electronic device, the operation end 422 is pushed to release the locking portion 424 from the locking slot 223. The heat dissipating module 40 can then be pulled out from the receiving portion 22.

In this embodiment, the electronic device utilizes an idle PSU receiving portion 22 for arranging a heat dissipating module 40, which can dissipate heat for the computer enclosure effectively and avoid disturbing the air flow in the housing 10.

Even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. An electronic device comprising:
a housing;
a circuit board arranged in the housing;
a power supply unit (PSU) bracket fixed in the housing, the PSU bracket comprising an idle PSU receiving portion; and
a heat dissipating module received in the idle PSU receiving portion, and electrically connected to the circuit board.

2. The electronic device of claim 1, wherein the heat dissipating module comprises a mounting frame, a fan received in the mounting frame, and a connecting plate extending out of the mounting frame, a connector is set on an end of the connecting plate to be electrically connected to the circuit board.

3. The electronic device of claim 2, wherein the mounting frame comprises a first plate to cover the idle receiving portion and a second plate perpendicularly connected to the first plate, the first plate defines a plurality of vents, the fan is fixed to an inner side of the first plate.

4. The electronic device of claim 3, wherein the PSU bracket comprises a side plate facing the sidewall, the side plate defines a locking slot; the second plate of the mounting frame defines a through slot, a through hole is defined in a joint between the first plate and the second plate of the mounting frame, a resilient piece is arranged in the mounting frame, the resilient piece comprises a fixing end fixed to an inner side of the second plate, an operation end opposite to the fixing end and extending through the through hole, and a locking portion protruding from the resilient piece to extend through the through slot, wherein when the heat dissipating module is being inserted into the receiving portion, the locking portion abuts against the side plate to be deformed, until the locking portion is locked in the locking slot.
